(19) United States
(12) Patent Application Publication
(10) Pub. No.: US 2023/0012513 A1
(43) Pub. Date: Jan. 19, 2023

(54) MEMORY DEVICE AND ELECTRONIC APPARATUS INCLUDING THE SAME

(71) Applicants: SAMSUNG ELECTRONICS CO.,LTD., Suwon-si (KR); INDUSTRY-ACADEMIC COOPERATION FOUDATION, YONSEI UNIVERSITY, Seoul (KR)

(72) Inventors: Jiyeon Ku, Yongin-si (KR); Hyowon Kim, Suwon-si (KR); Wonjun Jang, Suwon-si (KR); Heeyoon Noh, Seoul (KR)

(73) Assignees: SAMSUNG ELECTRONICS CO.,LTD., Suwon-si (KR); INDUSTRY-ACADEMIC COOPERATION FOUDATION, YONSEI UNIVERSITY, Seoul (KR)

(21) Appl. No.: 17/862,675

(22) Filed: Jul. 12, 2022

(30) Foreign Application Priority Data
Jul. 13, 2021 (KR) 10-2021-0091856
Oct. 5, 2021 (KR) 10-2021-0131970

(51) Int. Cl. H01L 45/00; H01L 27/24

(52) U.S. Cl. CPC H01L 45/06; H01L 45/1253; H01L 45/143; H01L 45/144; H01L 27/2463

(57) ABSTRACT

Provided is a memory device and an electronic device including the same. The memory device according to an example embodiment may include: a two-dimensional material layer including a two-dimensional material; a contact region in contact with an edge of the two-dimensional material layer; and an electrode which is electrically connected to the contact region and changes a domain of a region adjacent to the contact region of the two-dimensional material layer by an applied voltage.

### CROSS-REFERENCE TO RELATED APPLICATIONS

This application is based on and claims priority under 35 U.S.C. § 119 to Korean Patent Application No. 10-2021-0091856, filed on Jul. 13, 2021, and Korean Patent Application No. 10-2021-0131970, filed on Oct. 5, 2021, in the Korean Intellectual Property Office, the disclosures of which are incorporated by reference herein in their entireties.

### BACKGROUND

### 1. Field

The disclosure relates to a memory device and an electronic device including the same.

### 2. Description of the Related Art

The properties found in two-dimensional materials may be used for the development of new technologies, such as ultra-thin, flexible, nanoelectronic, and photoelectronic devices, and research is underway into such next-generation materials. It is necessary to precisely control and adjust the properties of the two-dimensional materials in order to utilize these two-dimensional materials as materials for new technological devices. The properties of the two-dimensional material include phase change, domain generation, grain boundary structure, etc. on the surface of the two-dimensional material, and it is expected that the two-dimensional material may be used as a next generation material by controlling the phase change, domain generation, grain boundary structure, etc.

In related art techniques used for controlling the above properties of a two-dimensional material, there is no method of controlling the properties of a local area of a part of the two-dimensional material other than a method of changing a phase or generating a domain over only the entire material.

### SUMMARY

Provided is a memory device for changing a domain of a local area through voltage application.

Provided are a method of forming the memory device and an operation method of the memory device.

Additional aspects will be set forth in part in the description which follows and, in part, will be apparent from the description, or may be learned by practice of the presented embodiments of the disclosure.

According to an aspect of the disclosure, there is provided a memory device including a two-dimensional material layer including a two-dimensional material, a contact region at an edge of the two-dimensional material layer and one or more electrodes which are electrically connected to the contact region and configured to apply voltage to change a domain of an adjacent region, which is adjacent to the contact region of the two-dimensional material layer.

The two-dimensional material layer may include a first two-dimensional material region having a first domain, based on a first voltage being applied by a first electrode among the one or more electrodes, the adjacent region is changed into a second two-dimensional material region having a second domain that is different from the first domain and a third two-dimensional material region having a third domain, and based on a voltage being applied by a second electrode among the one or more electrodes, the adjacent region is changed into the first two-dimensional material region.

First atoms included in the first two-dimensional material region may be aligned in a first direction, second atoms included in the second two-dimensional material region may be aligned in a second direction, and third atoms included in the third two-dimensional material region may be aligned in a third direction.

An angle between the first direction and the second direction may be 55 degrees to 65 degrees, an angle between the first direction and the third direction may be 55 degrees to 65 degrees, and an angle between the second direction and the third direction may be 115 degrees to 125 degrees.

The first atoms may be located at an uppermost end of a plurality of atoms included in the first two-dimensional material region, the second atoms may be located at an uppermost end of a plurality of atoms included in the second two-dimensional material region and the third atoms may be located at an uppermost end of a plurality of atoms included in the third two-dimensional material region, and the first domain, the second domain, and the third domain may have 1T′ phases having different alignment directions of the atoms, respectively.

At least two of the first two-dimensional material region, the second two-dimensional material region, and the third two-dimensional material region may have different properties in at least one of electrical properties, optical properties, thermal properties, magnetic properties, or crystalline structural properties.

A first boundary between the second two-dimensional material region and the third two-dimensional material region has a same direction as an alignment direction of atoms included in the first two-dimensional material region.

The second two-dimensional material region may include a first sub-region and a second sub-region facing each other based on the contact region, the third two-dimensional material region may include a third sub-region and a fourth sub-region facing each other based on the contact region, and the first sub-region, the second sub-region, the third sub-region, and the fourth sub-region form a rhombic shape.

At least one of the second two-dimensional material region or the third two-dimensional material region may have a triangular shape.

A region including the second two-dimensional material region and the third two-dimensional material region may have a size of 200 nm² to 3000 nm².

The contact region may include at least one of a hole structure, a groove structure, or a step terrace structure.

The contact region may have a long-axis length of 10 nm to 200 nm.

The contact region may have a depth of 0.07 nm to 1 nm.

The two-dimensional material may include transition metal dichalcogenide (TMD).

The two-dimensional material may include at least one of MoS₂, MoTe₂, MoSe₂, WS₂, WSe₂, or WTe₂.

The voltage may be applied by the one or more electrodes at a direction parallel to a planar surface of the two-dimensional material layer.

The voltage applied by the one or more electrodes may be −2 V to −4 V.

The voltage applied by the one or more electrodes may be applied for 50 ms to 400 ms.

The memory device may further include a source region, and a drain region spaced apart from the source region.

According to another aspect of the disclosure, there is provided an electronic device including a memory device including a two-dimensional material layer including a two-dimensional material, a contact region at an edge of the two-dimensional material layer and one or more electrodes which are electrically connected to the contact region and configured to apply voltage to change a domain of an adjacent region, which adjacent to the contact region of the two-dimensional material layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view illustrating a surface of a memory device according to an example embodiment;

FIG. 2 is a flowchart illustrating a method of forming a memory device, according to an example embodiment, and an operation method of the memory device;

FIG. 3A is a diagram illustrating a two-dimensional material layer used to form a memory device according to an example embodiment;

FIGS. 3B, 3C and 3D are diagrams illustrating a heterogeneous 1T′ phase of MoTe₂;

FIG. 4A is a diagram illustrating a region of the two-dimensional material layer of FIG. 3A, and a probe arranged on the region;

FIGS. 4B and 4C are graphs respectively showing probe height and voltage application of a scanning probe microscope over time in a method of forming a memory device, according to an example embodiment, and an operating method thereof;

FIG. 5A is a view showing that a probe is brought into contact with a hole of a two-dimensional material layer that is smaller than a plane size of a height of the probe during an operation of a memory device;

FIG. 5B is a view showing that a probe is brought into contact with a hole of a two-dimensional material layer that is greater than a plane size of a height of the probe during an operation of a memory device;

FIG. 6A is a micrograph illustrating a region including a heterogeneous domain formed when a probe is positioned as shown in FIG. 5A;

FIG. 6B is a micrograph illustrating a region including a heterogeneous domain formed when a probe is positioned as shown in FIG. 5B;

FIG. 7 is a micrograph of forming a heterogeneous domain in a memory device including MoTe₂ by using a method of operating the memory device, according to an example embodiment;

FIG. 8 is a micrograph of the second two-dimensional material region, the third two-dimensional material region, and the first boundary of FIG. 7;

FIG. 9 is a micrograph of the first two-dimensional material region, the second two-dimensional material region, and the third boundary of FIG. 7;

FIG. 10 is a conceptual diagram illustrating a memory device according to an example embodiment;

FIGS. 11A and 11B are a cross-sectional view and a plan view of a memory device according to an example embodiment, respectively;

FIG. 11C and FIG. 11D are conceptual views illustrating that an electrode connected to the memory device of FIG. 11B is used to cause phase change of the memory device;

FIG. 12 is a cross-sectional view illustrating a memory device according to an example embodiment;

FIG. 13 is a block diagram of an electronic device including a memory device according to an example embodiment;

FIG. 14 is a block diagram of an information processing system including a memory device according to an example embodiment; and

FIG. 15 is a block diagram of a memory card including a memory device according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The embodiments described below are merely exemplary and various modifications are possible from these embodiments. In the following drawings, the same reference numerals refer to the same components, and the size of each component in the drawings may be exaggerated for clarity and convenience of description.

Hereinafter, the term “upper portion” or “on” may also include “to be present above, below, in the left and right sides on a non-contact basis” as well as “to be on the top, bottom, left, and right portions in directly contact with”. Hereinafter, the term “lower portion” or “bottom” may also include “to be present below on a non-contact basis” as well as “to be on the bottom in directly contact with”.

The singular expression includes plural expressions unless the context clearly implies otherwise. In addition, when a part “includes” a component, this means that it may further include other components, not excluding other components unless otherwise opposed.

The use of the term “the” and similar indicative terms may correspond to both singular and plural.

The meaning of “connection” may include not only physical connection, but also optical connection, electrical connection, etc.

In addition, the use of all illustrative terms (e.g., etc.) is simply intended to detail technical ideas and, unless limited by the claims, the scope of rights is not limited due to such illustrative terms.

The terms first, second, etc. may be used to describe various components, but the components should not be limited by terms. Terms are used only to distinguish one component from another.

The fact that one length unit such as height, depth, and thickness are equal to or substantially the same as another may include a difference within an error range recognized by those skilled in the art.

A domain may be a region having spontaneous polarization in the same direction. The difference between two domains may mean that the spontaneous polarization directions of two regions are different, and for example, a second domain having different spontaneous polarization directions from a first domain may be referred to as a heterogeneous domain of the first domain.

A domain boundary may be an interface of regions having spontaneous polarization in different directions. That is, the domain boundary may mean an interface of heterogeneous domains.

A two-dimensional material is a material in which several nanometers of atoms are arranged in a single layer, that is, a crystalline material composed of a single layer of atoms.

The 1T phase is a phase in which the metal coordination is in an octahedral form, and the chalcogen atoms surrounding the transition metal atom form the octahedral structure.

The 1T′ phase is a phase having a distorted version in a structure of the 1T phase, and chalcogen atoms surrounding the transition metal atom of the 1T′ phase form an octahedral structure, but in this case, the symmetry of the octahedral is relatively lower than that of the 1T phase.

The 2H phase is a phase in which the metal coordination is in the form of a trigonal prismatic shape, and the chalcogen atoms surrounding the transition metal atom form a triangular prism structure.

Each of the 1T phase, 1T′ phase, and 2H phase has a different metal coordination, and thus, a top view structure and a stacking sequence may be different when viewed in a plane.

The edge region may be an edge region of the two-dimensional material, but may be a region that is not a flat surface of the two-dimensional material, and may be referred to as a region in which the thickness direction of the layer structure of the atoms constituting the two-dimensional material is exposed.

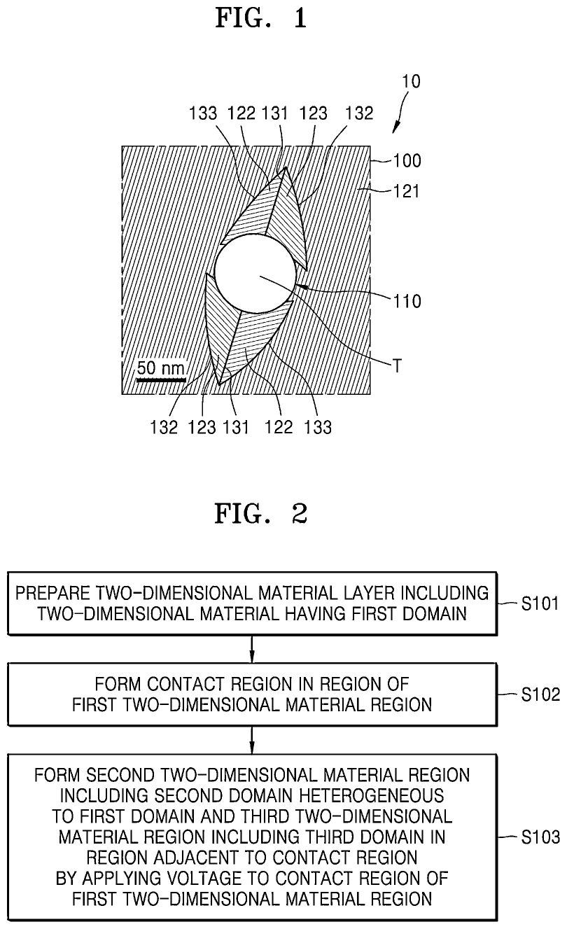

FIG. 1 is a plan view illustrating a surface of a memory device according to an example embodiment.

Referring to FIG. 1, a memory device 10 according to an example embodiment may include a two-dimensional material layer 100 including a two-dimensional material, and a contact region 110 contacting an edge of the two-dimensional material layer 100. According to an example embodiment, electrodes may be provided, which are electrically connected to the contact region 110. According to an example embodiment, a domain of a region adjacent to the contact region 110 of the two-dimensional material layer 100 may change based on an applied voltage. The two-dimensional material layer 100 may include a first two-dimensional material region 121 having a first domain, and when a voltage is applied by a first electrode of the electrodes, a region adjacent to the contact region 110 may be changed to a second two-dimensional material region 122 having a second domain heterogeneous to the first domain, and a third two-dimensional material region 123 having a third domain, and when a voltage is applied by a second electrode of the electrodes, the region adjacent to the contact region 110 may be changed to the first two-dimensional material region 121. The first two-dimensional material region 121 including the first domain, the second two-dimensional material region 122 including the second domain, and the third two-dimensional material region 123 including the third domain may have different atomic alignment directions for each region. According to an example embodiment, the atomic alignment directions for each region may be predetermined. Accordingly, at least two of the first two-dimensional material region 121, the second two-dimensional material region 112, and the third two-dimensional material region 123 may have different properties in at least one of physical properties and chemical properties, for example, electrical properties, optical properties, thermal properties, magnetic properties, and crystalline structural properties. These properties of the memory device 10 according to an example embodiment may be applied to a memory device using a phase change or the like.

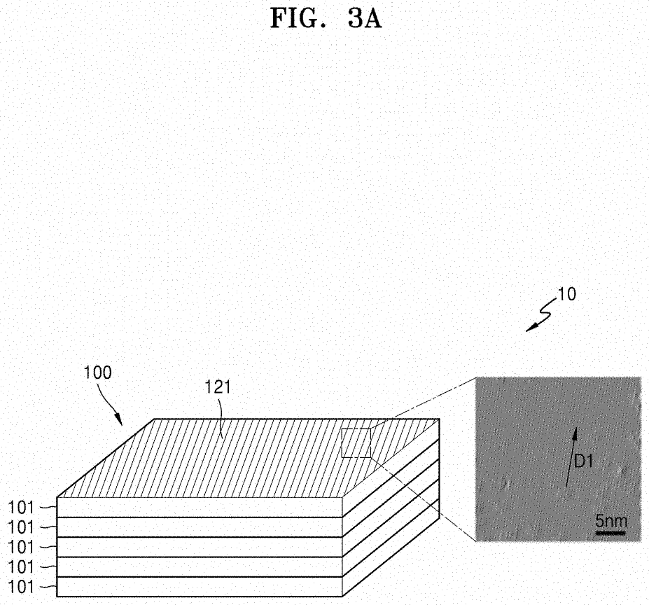

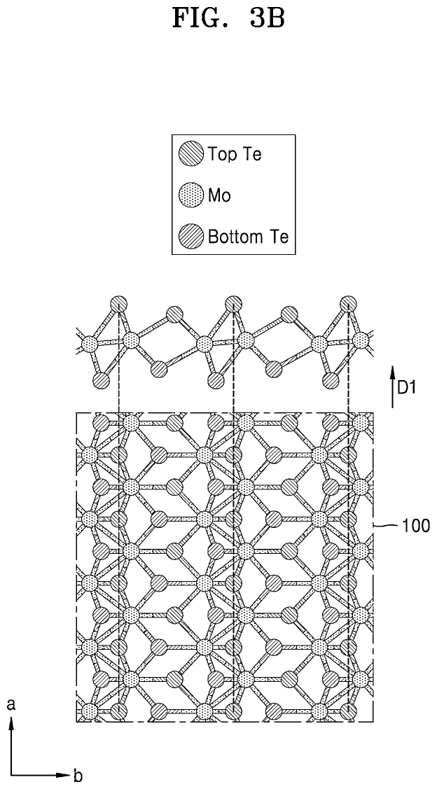

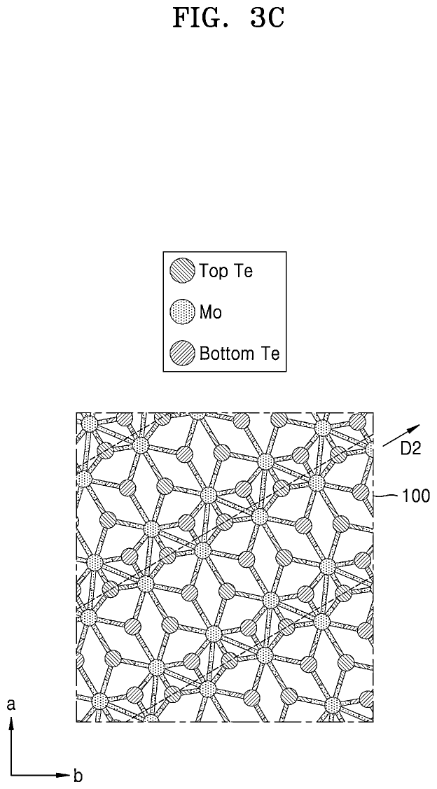

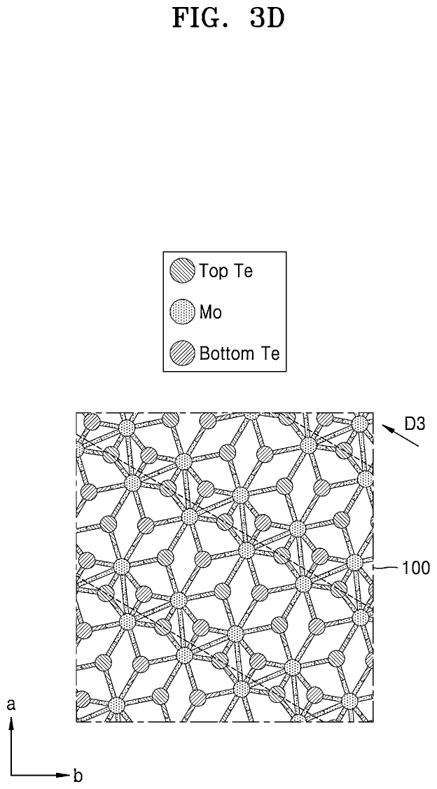

The memory device 10 according to an example embodiment may include the two-dimensional material layer 100. A first two-dimensional material region 121 having a first domain may be included on one surface of the two-dimensional material layer 100. The two-dimensional material layer 100 may include a two-dimensional material, and the two-dimensional material layer 100 may be a two-dimensional material single layer 101 or a multi-layer in which two-dimensional material single layers 101 are stacked on one another as shown in FIG. 3A. The surface of the two-dimensional material layer 100 may have a first domain. For example, the surface of the two-dimensional material layer 100 of the memory device 10 may be a first two-dimensional material region 121 having a first domain as a whole. The first two-dimensional material region 121 including the first domain may be a region in which a predetermined atomic alignment direction is aligned in a first direction D1.

When a voltage by the first electrode of the electrodes is applied to the memory device 10, a local region on the surface of the two-dimensional material layer 100 may be changed from the first two-dimensional material region 121 having the first domain to a region having a heterogeneous domain heterogeneous to the first domain. In this case, the first two-dimensional material region 121 may remain as it is except for the local region. In addition, when a voltage by the second electrode among the electrodes is applied to the memory device 10, a region having a heterogeneous domain on a surface of the two-dimensional material layer 100 may be changed back to the first two-dimensional material region 121.

The two-dimensional material layer 100 may include transition metal dichalcogenide (TMD). The TMD may have several phases, for example, 1T, 1T′, and 2H phases. For example, the two-dimensional material layer 100 may include a group VI TMD, and the group VI TMD may include MoS₂, MoTe₂, MoSe₂, WS₂, WSe₂, WTe₂ or the like. However, the two-dimensional material is not limited to including the TMD, and may include other two-dimensional materials. For example, the two-dimensional material included in the memory device 10 may be a material having a property in which a single layer of the two-dimensional material is formed of a unit having a two-layer structure or a three-layer structure of atoms constituting the two-dimensional material.

The two-dimensional material, for example, the TMD, may have a 1T′ phase. For example, the 1T′ phase of the metal dichalcogenide may include heterogeneous 1T′ phases, and the heterogeneous 1T′ phases may have different predetermined atomic alignment directions in the metal dichalcogenide. The difference in the predetermined atomic alignment direction according to the heterogeneous phase is not limited to those applied only to TMD, and may also be applied to other two-dimensional materials. For example, an alignment direction of the predetermined atoms included in a material having the first phase may form a predetermined angle with an alignment direction of the predetermined atoms included in a material having a second phase that is heterogeneous to the first phase. The predetermined atoms may be atoms located at the uppermost end of atoms included in regions each having heterogeneous phases. For example, in the case of MoTe₂, the predetermined atoms may be tellurium (Te) located at the uppermost end. The predetermined atoms are not limited to a chalcogen atom located at the uppermost end, but may be other atoms located at the uppermost end, and may be atoms located at one end that is not the uppermost end.

Different domains on the surface of the two-dimensional material layer 100 may include two-dimensional materials that are heterogeneous 1T′ phases, respectively. The first domain may include the two-dimensional material in the first 1T′ phase, the second domain may include the two-dimensional material in the second 1T′ phase, and the third domain may include the two-dimensional material in the third 1T′ phase. The second domain and the third domain may be referred to as heterogeneous domains of the first domain. A grain boundary may be formed between different domains or between two-dimensional material regions corresponding to different domains.

The memory device 10 according to an example embodiment may include a contact region 110 in contact with an edge of the two-dimensional material layer 100. For example, the contact region 110 may have a hole, groove, or step-terrace structure arranged on the top of the surface of the two-dimensional material layer 100. However, the contact region 110 is not limited thereto and may be a region in which at least one layer of the top of the surface of the two-dimensional material layer 100 is locally depressed or etched to contact an edge of one layer of the two-dimensional material layer 100. The depth of the contact region 110 may be greater than the thickness of one layer included in the two-dimensional material layer 100 or may be substantially equal to the thickness of the one layer.

However, the contact region 110 is not limited to being formed on the top of the surface of the two-dimensional material layer 100 and may be a region that is not a plane of the two-dimensional material layer 100 and is in contact with a surface in a thickness direction of the two-dimensional material layer 100. A region in contact with a surface of the two-dimensional material layer 100 in the thickness direction may be in contact with an edge of the two-dimensional material layer 100. In this case, when the memory device 10 is formed, a separate etching process or a depression process for forming the contact region 110 may not be required.

The contact region 110 is a location where a voltage is applied through an electrode, and the voltage may be applied to an edge of the two-dimensional material layer 100 through the contact region 110.

When the contact region 110 includes, for example, a hole, groove, or step-terrace structure, the long-axis length of the plane of the contact region 110 may be 10 nm to 200 nm. Here, the long-axis length may mean the maximum distance among distances between two points on a plane. In addition, the contact region 110 may have a depth of 0.07 nm to 1 nm, for example, a depth of 0.1 nm to 0.2 nm.

In the electrode included in the memory device 10 in accordance with the example embodiment, when a voltage is applied through the electrode, the domain of a region adjacent to the contact region 110 may be changed. In the case that the surface of the two-dimensional material layer 100 is the first two-dimensional material region 121 having the first domain, when a voltage is applied through the first electrode among the electrodes, a second two-dimensional material region 122 having a second domain and a third two-dimensional material region 123 having a third domain may be formed in a region adjacent to the contact region 110. When a voltage is applied through the second electrode of the electrodes, the second two-dimensional material region 122 and the third two-dimensional material region 123 may return to the first two-dimensional material region 121.

The second two-dimensional material region 122 may contact each of the contact region 110, the first two-dimensional material region 121, and the third two-dimensional material region 123, and the third two-dimensional material region 123 may contact each of the contact region 110, the first two-dimensional material region 121, and the second two-dimensional material region 122.

The first two-dimensional material region 121 including the first domain, the second two-dimensional material region 122 including the second domain, and the third two-dimensional material region 123 including the third domain may have different predetermined atomic alignment directions. Here, the predetermined atoms may be atoms positioned at the uppermost end of atoms included in the first two-dimensional material region 121, the second two-dimensional material region 122, and the third two-dimensional material region 123. For example, the two-dimensional material layer 100 may include MoTe₂. In this case, the predetermined atoms may be tellurium positioned on the top thereof (Top Te). In a region including MoTe₂ in the first 1T′ phase, that is, in the first two-dimensional material region 121 having the first domain, atoms of tellurium positioned on the top (Top Te) may be aligned in the first direction D1, in a region including MoTe₂ in the second 1T′ phase, that is, in the second two-dimensional material region 122 having the second domain, Top Te atoms may be aligned in the second direction D2, and in a region including MoTe₂ in the third 1T′ phase, that is, in the third two-dimensional material region 123 having the third domain, Top Te atoms may be aligned in the third direction D3.

An angle between the first direction D1 in the first two-dimensional material region 121 and the second direction D2 in the second two-dimensional material region 122 may be a predetermined angle. When the two-dimensional material layer 100 includes MoTe₂, the first direction D1 may form an angle of 60 degrees with the second direction D2, the first direction D1 may form an angle of 60 degrees with the third direction D3, and the second direction D2 may form an angle of 120 degrees with the third direction D3. However, the embodiments are not limited to the above examples, and an angle between two of the first direction D1, the second direction D2, and the third direction D3 may be different according to a material included in the two-dimensional material layer 100.

A third boundary 133 may be formed at an interface between the first two-dimensional material region 121 and the second two-dimensional material region 122, a second boundary 132 may be formed at an interface between the first two-dimensional material region 121 and the third two-dimensional material region 123, and a first boundary 131 may be formed at an interface between the second two-dimensional material region 122 and the third two-dimensional material region 123. The first boundary 131 may have the same direction as the alignment direction of predetermined atoms included in the first two-dimensional material region 121. For example, when the two-dimensional material layer 100 includes MoTe₂, the first boundary 131 may have the same direction as the Top Te atomic alignment direction of the first two-dimensional material region 121. Each of the first boundary 131, the second boundary 132, and the third boundary 133 may be a grain boundary. Each of the first boundary 131, the second boundary 132, and the third boundary 133 may have different properties from the first domain, the second domain, and/or the third domain.

The first direction D1, the second direction D2, and the third direction D3 may be different from one another. Accordingly, at least two of the first two-dimensional material region 121, the second two-dimensional material region 112, and the third two-dimensional material region 123 may have different properties in physical properties or chemical properties, for example, electrical properties, optical properties, thermal properties, magnetic properties, or crystalline structural properties. The memory device may be implemented by changing the first two-dimensional material region 121 to the second two-dimensional material region 122 and the third two-dimensional material region 123, or vice versa.

In the above example, it has been described that one region of one material is changed from one 1T′ phase to another 1T′ phase heterogeneous to the 1T′ phase, forming the memory element 10. However, the embodiments are not limited thereto, and one region of one material may be changed from one 2H phase to a different 1T′ phase heterogeneous to the 2H phase, forming the memory device 10 having a 2H-1T′ phase.

A region (hereinafter, a region including the heterogeneous domain) including the second two-dimensional material region 122 and the third two-dimensional material region 123, which are locally formed, may have a size of 200 nm² to 3000 nm², for example, 500 nm² to 2200 nm². Alternatively, each of the second two-dimensional material region 122 and the third two-dimensional material region 123 may have a size of 100 nm² to 1500 nm², for example, a size of 250 nm² to 1100 nm².

The region including the heterogeneous domain may have various shapes depending on the position of the electrode connected to the contact region 110. For example, when the entire circumferential surface of the electrode substantially contacts the edge of the two-dimensional material layer 100 through the contact region 110, the region including the heterogeneous domains formed through voltage application may have a rhombus shape. In this case, based on the contact region 110, sub-regions included in the second two-dimensional material region 122 may be disposed to face each other, and sub-regions included in the third two-dimensional material region 123 may be disposed to face each other. Alternatively, when one point to half the circumferential surface of the electrode contacts the edge of the two-dimensional material layer 100 through the contact region 110, the region including the heterogeneous domains formed through voltage application may have a triangular shape.

A voltage applied by the electrode may be −2 V to −4 V, and for example, a voltage within −2.5 V to −3 V may be applied through the contact region 110. For example, the voltage may be applied in an in-plane direction, that is, in a direction parallel to the plane of the two-dimensional material layer. For example, the voltage may be applied in a direction substantially parallel to a predetermined atomic alignment direction in the first two-dimensional material region 121. Alternatively, the voltage may be applied in a direction substantially parallel to a predetermined atomic alignment direction in the second two-dimensional material region 122 or the third two-dimensional material region 123, which is formed. In addition, the voltage applied by the electrode may be applied for 50 ms to 400 ms. However, the embodiments are not limited to the above range, and the range may be changed depending on the two-dimensional material included in the two-dimensional material layer 100, the material included in the electrode, or the like.

An electrode included in the memory device 10 according to an example embodiment may be an electrode directly connected to the contact region 110, but is not limited thereto and may be an electrode electrically connected to the contact region 110 through a contact part. For example, the electrode may be a probe 200 of a scanning probe microscope, but is not limited thereto.

Next, a method of forming and operating the memory device 10 will be described.

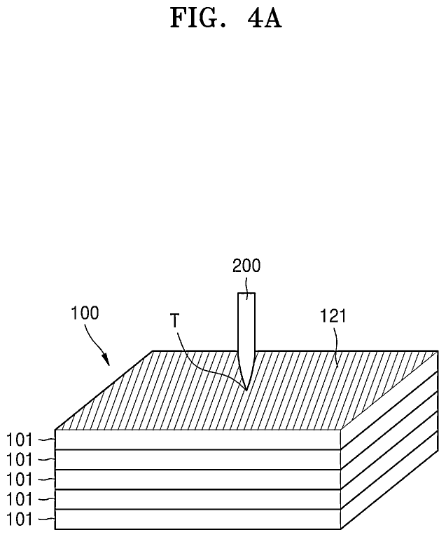

FIG. 2 is a flowchart illustrating a method of forming a memory device, according to an example embodiment, and an operation method of the memory device. FIG. 3A is a diagram illustrating a two-dimensional material layer used to form a memory device according to an example embodiment. FIGS. 3B, 3C and3D are diagrams illustrating a heterogeneous 1T′ phase of MoTe₂. FIG. 4A is a diagram illustrating a predetermined region of the two-dimensional material layer of FIG. 3A, and a probe arranged on the predetermined region. FIGS. 4B and 4C are graphs respectively showing probe height and voltage application of a scanning probe microscope over time in a method of forming a memory device, according to an example embodiment, and an operating method thereof.

According to FIGS. 2, 3A, 3B, 3C, 4A, 4B and 4C, the method of forming a memory device 10, according to an example embodiment, may include preparing a two-dimensional material layer 100 including a first two-dimensional material region 121 having a first domain, and forming a contact region in a region of the first two-dimensional material region 121, and the method of operating the memory device 10, according to an example embodiment, may include forming, in a region adjacent to the contact region 110, a second two-dimensional material region 122 including a second domain heterogeneous to the first domain and a third two-dimensional material region 123 having a third domain, by applying a voltage to the contact region 110 of the first two-dimensional material region 121. According to an example embodiment, the contact region may be formed at a predetermined region of the first two-dimensional material region 121. The first domain, the second domain, and the third domain may be different domains, respectively. After having formed the second two-dimensional material region 122 and the third two-dimensional material region 123, the heterogeneous domain region formed in a region adjacent to a predetermined region T may include a second two-dimensional material region 122 including a second domain and a third two-dimensional material region 123 including a third domain.

Referring to FIG. 3A, the method of forming a memory device 10, according to an example embodiment, may include a preparation operation S101 of preparing a two-dimensional material layer 100 including a first two-dimensional material region 121 having a first domain. The first two-dimensional material region 121 having a first domain may be located on one surface of the two-dimensional material layer 100. The two-dimensional material layer 100 may include a two-dimensional material, and the two-dimensional material layer 100 may be a two-dimensional material single layer 101 or a multi-layer in which two-dimensional material single layers 101 are stacked on one another. The surface of the two-dimensional material layer 100 may have a first domain. For example, before forming the memory device 10, the surface of the two-dimensional material layer 100 may be a first two-dimensional material region 121 having a first domain as a whole. The first two-dimensional material region 121 including the first domain may be a region in which a predetermined atomic alignment direction is aligned in a first direction D1.

The two-dimensional material layer 100 may include TMD. The TMD may have several phases, for example, 1T, 1T′, and 2H phases. For example, the two-dimensional material layer 100 may include a group VI TMD, and the group VI TMD may include MoS₂, MoTe₂, MoSe₂, WS₂, WSe₂, WTe₂ or the like. However, the two-dimensional material is not limited to including the TMD, and may include other two-dimensional materials. For example, the two-dimensional material included in the memory device 10 may be a material having a property in which a single layer of the two-dimensional material is formed of a unit having a two-layer structure or a three-layer structure of atoms constituting the two-dimensional material.

The two-dimensional material, for example, the TMD, may have a 1T′ phase. The 1T′ phase of the two-dimensional material, for example, the metal dichalcogenide, may include heterogeneous 1T′ phases, and the heterogeneous 1T′ phases may have different predetermined atomic alignment directions in the metal dichalcogenide. The difference in the predetermined atomic alignment direction according to the heterogeneous phase is not limited to those applied only to TMD, and may also be applied to other two-dimensional materials. The predetermined atoms may be atoms located at the uppermost end of atoms included in regions each having heterogeneous phases. For example, in the case of MoTe₂, the predetermined atoms may be tellurium (Te) located at the uppermost end. For example, an alignment direction of the predetermined atoms included in a material having the first phase may form a predetermined angle with an alignment direction of the predetermined atoms included in a material having a second phase that is heterogeneous to the first phase. The predetermined atoms are not limited to a chalcogen atom located at the uppermost end, and may be other atoms located at the uppermost end, and may be atoms located at one end that is not the uppermost end.

Different domains on the surface of the two-dimensional material layer 100 may include two-dimensional materials that are heterogeneous 1T′ phases, respectively. The first domain may include the two-dimensional material in the first 1T′ phase, the second domain may include the two-dimensional material in the second 1T′ phase, and the third domain may include the two-dimensional material in the third 1T′ phase. A grain boundary may be formed between different domains or between two-dimensional material regions corresponding to different domains. The entire surface of the two-dimensional material layer 100 of the preparation operation S101 may have a first domain, or a main region of the one surface may have a first domain. In this case, the main region of one surface may be a region that occupies 50% or more of the regions arranged on one surface.

In a region including MoTe₂ in the first 1T′ phase of FIG. 3B, that is, in the first two-dimensional material region 121 having the first domain, tellurium atoms positioned on the top (Top Te) may be aligned in the first direction D1, in a region including MoTe₂ in the second 1T′ phase of FIG. 3C, that is, in the second two-dimensional material region 122 having the second domain, Top Te atoms may be aligned in the second direction D2, and in a region including MoTe₂ in the third 1T′ phase of FIG. 3D, that is, in the third two-dimensional material region 123 having the third domain, Top Te atoms may be aligned in the third direction D3. In this case, the first direction D1 may form an angle of 60° with the second direction D2, the first direction D1 may form an angle of 60° with the third direction D3, and the second direction D2 may form an angle of 120° with the third direction D3.

The first direction D1, the second direction D2, and the third direction D3 may be different from one another. Accordingly, at least two of the first two-dimensional material region 121, the second two-dimensional material region 112, and the third two-dimensional material region 123 may have different properties in physical properties or chemical properties, for example, electrical properties, optical properties, thermal properties, magnetic properties, or crystalline structural properties.

In the above example, it has been described that one region of one material is changed from one 1T′ phase to another 1T′ phase heterogeneous to the 1T′ phase, forming the memory element 10. However, the embodiments are not limited thereto, and one region of one material may be changed from one 2H phase to a different 1T′ phase heterogeneous to the 2H phase, forming the memory device 10 having a 2H-1T′ phase.

The method of forming the memory device 10, according to an example embodiment, may include forming a contact region in a predetermined region T of the first two-dimensional material region 121 (S102). The forming of the contact region in the predetermined region T may include, for example, forming a hole in the predetermined region T, forming a groove in a surface of the predetermined region T, forming a step-terrace structure on a surface of the predetermined region T, or the like. However, the embodiments are not limited thereto. That is, the forming of the contact region in the predetermined region T may include locally depressing or etching at least one layer on the top of the surface of the predetermined region T by using other methods. The predetermined region T may be depressed or etched to form the contact region 110, and for example, the contact region 110 may be a hole, groove, or step-terrace structure. The depth of the contact region 110 may be greater than the thickness of one layer included in the two-dimensional material layer 100 or may be substantially equal to the thickness of the one layer.

However, the contact region 110 is not limited to a region having a depth, such as a region to be depressed or etched. The contact region 110 may be a region contacting an edge of at least one surface of the two-dimensional material layer 100, and may be a region capable of applying a pulse, such as a voltage, to the edge of the at least one surface. Accordingly, when the edge exposed on the surface of the two-dimensional material layer 100 in the thickness direction serves as the contact region 110, there is no need to form the contact region 110 separately.

For example, the contact region 110 may be formed in the predetermined region T by applying pressure to the predetermined region T by a probe of a scanning probe microscope (SPM), but is not limited thereto and a height difference may be formed in other methods.

The long-axis length of the contact region 110 formed in the contact region forming operation (S102), for example, the long-axis length of the plane having a hole, groove, or step-terrace structure, may be 10 nm to 200 nm. Here, the long-axis length may mean the maximum distance among distances between two points on a plane.

Referring to FIGS. 4A, 4B and 4C, the method of operating the memory device 10, according to an example embodiment, may include operation S103 of forming, in a region adjacent to the predetermined region T, a second two-dimensional material region 122 including a second domain heterogeneous to the first domain and a third two-dimensional material region 123 having a third domain by applying a voltage to the predetermined region T of the first two-dimensional material region 121. Here, the second domain and the third domain may be referred to as heterogeneous domains of the first domain. The predetermined region T may be a region included in the contact region 110.

A method of locally applying a voltage to a predetermined region T of the first two-dimensional material region 121 may be performed in various ways, for example, the voltage may be applied to the predetermined region T through an electrode. For example, the electrode may include a probe 200, which is a conductor, and the probe 200 has a conical structure and thus may apply a voltage to a local region. For example, the probe 200 may be a probe of an SPM. The SPM is a microscope that can measure the atomic and electronic structure of a material to approximately 0.01 nm. The probe 200 of the SPM may be relatively accurately disposed in a predetermined region T of the two-dimensional material layer 100, and may induce a phase change only in a local part adjacent to the predetermined region T. The horizontal resolution of the scanning probe microscope may be 0.01 nm to 0.1 nm, and the vertical resolution may be 0.001 nm to 0.01 nm. The end portion of the probe 200 of the scanning probe microscope may have a conical shape with one atom end. The method of locally applying the voltage to the predetermined region T of the first two-dimensional material region 121 may include a method of applying the voltage by a direct or indirect method in addition to applying the voltage through an electrode. In addition, a voltage may be locally applied to the predetermined region T by using a voltage applying means besides the electrode.

Referring to FIGS. 4A and 4B, the contact region forming operation S102 may include applying pressure to the predetermined region T with, for example, a probe 200 of a scanning probe microscope to penetrate the probe 200 into the two-dimensional material layer 100. In the operation of penetrating the probe 200 of the scanning probe microscope into the two-dimensional material layer 100, pressure may be applied to the predetermined region T of the first two-dimensional material region 121, and the contact region 110 may be locally formed in the predetermined region T to which pressure is applied. When the two-dimensional material layer 100 is a single layer, a hole may be formed by locally removing the predetermined region T of the surface of the two-dimensional material layer 100. Alternatively, when the two-dimensional material layer 100 is a multilayer, a hole may be formed by locally removing at least one layer of the predetermined region T of the surface of the two-dimensional material layer 100.

Referring to FIG. 4B, in the penetration operation, the penetration depth of the probe 200, the penetration time T1 of the probe 200, and the time T3 for releasing the probe 200 may be appropriately selected. The x-axis of FIG. 4B may represent time (ms), and the y-axis may represent the height (nm) of the probe 200 or the depth (nm) recessed by the probe 200. The penetration depth of the probe 200 may be 0.07 nm to 1 nm, the penetration time T1 of the probe 200 may be 0.5 s to 4 s, and the time T3 for releasing the probe 200 may be 50 ms or less. For example, the penetration depth of the probe 200 may be 0.1 nm to 0.2 nm, the penetration time T1 of the probe 200 may be 0.5 s to 3 s, and the time T3 for releasing the probe 200 may be 20 ms.

The penetration operation and the two-dimensional region forming operation S103 may occur continuously, or some processes may be performed simultaneously. Referring to FIG. 4C, a voltage may be applied to the predetermined region T of the two-dimensional material layer 100 through the probe 200 of the scanning probe microscope. The x-axis of FIG. 4C may indicate time (ms), and the y-axis may indicate voltage (V). For example, the voltage may be applied in the form of a pulse. When the probe 200 of the scanning probe microscope penetrates to a maximum depth, voltage may start to be applied, and when the probe 200 penetrates to a maximum depth and stays at a predetermined depth, voltage may be continuously applied. For example, a time at which the probe 200 penetrates the two-dimensional material layer 100 may be T1, and a voltage may be applied to the probe 200 after the probe 200 is penetrated (after an elapse of time T1). When the scanning probe microscope penetrates to a maximum depth, a pulse-type voltage may be applied, and in this case, the voltage may be −2 V to −4 V. For example, the applied voltage may be −2.5 V to −3 V. The time T2 at which the voltage is applied may be 50 ms to 1000 ms, for example, 100 ms to 300 ms. The time T2 at which the voltage is applied may be appropriately selected according to the formation of the heterogeneous domain. A voltage may be applied after the scanning probe microscope penetrates to a maximum depth. However, the embodiments are not limited thereto, and a voltage may be applied together with the penetration. The application of voltage may continue while taking out the probe, but is not limited thereto. The direction of applying the voltage need not be separately considered, or the direction of applying the voltage may be appropriately selected. For example, a voltage may be applied in an in-plane direction, but is not limited thereto. The in-plane direction may be any direction in the plane of the two-dimensional material single layer 101. For example, the in-plane direction may be a direction parallel to a predetermined atomic alignment direction D1 in the first two-dimensional material region 121 having the first domain. The applied voltage may allow energy to be transferred in a direction parallel to a predetermined atomic alignment direction D1 of predetermined atoms (for example, Top Te) included in the first two-dimensional material region 121 having the first domain, thereby inducing tensile deformation. A grain boundary formed between the second two-dimensional material region 122 having the second domain and the third two-dimensional material region 123 having the third domain may be formed in a direction parallel to the Top Te atomic alignment direction D1 of the first two-dimensional material region 121.

The method of operating the memory device 10, according to an example embodiment, may include operation S103 of forming, in a region adjacent to the predetermined region T, a second two-dimensional material region 122 including a second domain heterogeneous to the first domain and a third two-dimensional material region 123 having a third domain, by applying a voltage to the predetermined region T of the first two-dimensional material region 121. For example, the second two-dimensional material region 122 and the third two-dimensional material region 123 may be locally formed only in a region adjacent to the predetermined region T to which pressure and voltage are applied by the probe 200. The predetermined region T and a region adjacent to the predetermined region T may each have a first domain before the contact region operation S102. After the contact region formation S102 and the two-dimensional region formation S103, the contact region 110 is formed in the predetermined region T, and the region adjacent to the predetermined region T may have a second domain and a third domain. The second domain may be different from the first domain, and the third domain may be different from the first domain and the second domain. Each of the first domain, the second domain, and the third domain may include a heterogeneous 1T′-phase material. For example, the first domain may include the two-dimensional material in the first 1T′ phase, the second domain may include the two-dimensional material in the second 1T′ phase, and the third domain may include the two-dimensional material in the third 1T′ phase. A contact region 110 may be formed in the predetermined region T, and the second two-dimensional material region 122 and the third two-dimensional material region 123 may be arranged between the contact region 110 and the first two-dimensional material region 121. The edges of the second two-dimensional material region 122 may contact the first two-dimensional material region 121, the third two-dimensional material region 123, and the contact region 110, respectively. The edges of the third two-dimensional material region 123 may contact the first two-dimensional material region 121, the second two-dimensional material region 122, and the contact region 110, respectively. In the region (the second two-dimensional material region 122 and the third two-dimensional material region 123) in which the domains heterogeneous to the first domain are formed, the lattice constant in the unit cell “a” direction after formation of the heterogeneous domain is different, at a difference of 2.5% to 5%, from the lattice constant in the unit cell “a” direction before the heterogeneous domain is formed. For example, in the case of MoTe₂, there may be a difference of 3.5%. This may mean that formation of a heterogeneous domain region is induced through tensile deformation.

The first two-dimensional material region 121 including the first domain, the second two-dimensional material region 122 including the second domain, and the third two-dimensional material region 123 including the third domain may have different predetermined atomic alignment directions. For example, when the two-dimensional material layer 100 includes MoTe₂, the Top Te atomic alignment direction of the first two-dimensional material region 121 may be the first direction D1, the Top Te atomic alignment direction of the second two-dimensional material region 122 may be the second direction D2, and the Top Te atomic alignment direction of the third two-dimensional material region 123 may be the third direction D3. Two of the first direction D1, the second direction D2, and the third direction D3 may form a predetermined angle.

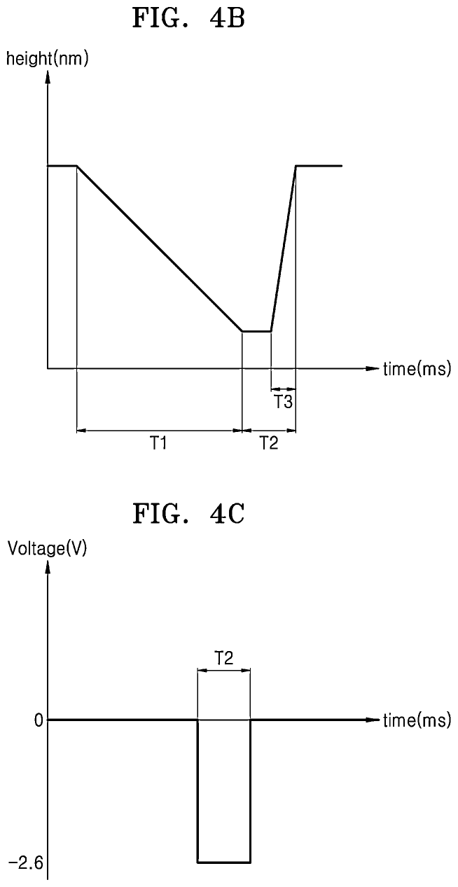

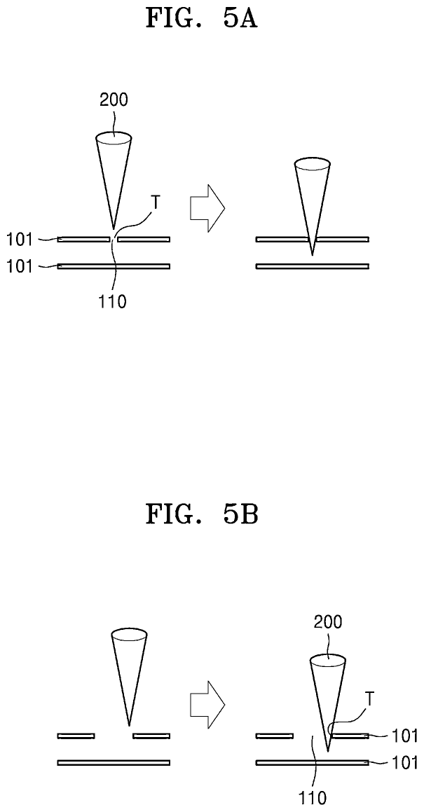

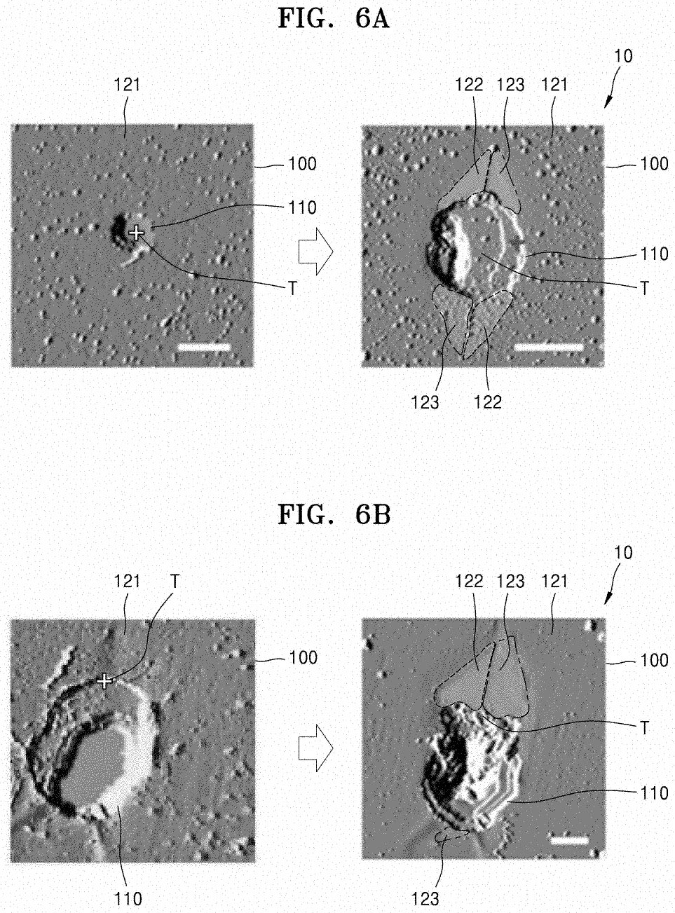

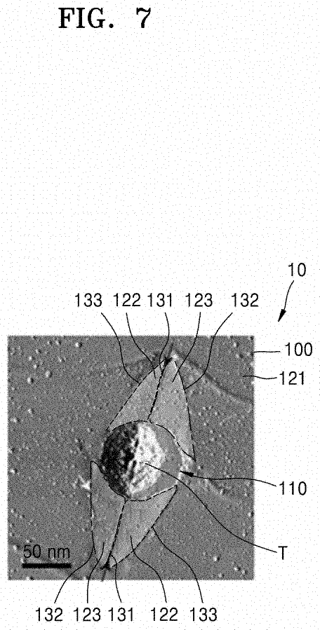

FIG. 5A is a view showing that a probe is brought into contact with a hole of a two-dimensional material layer that is smaller than a plane size of a height of the probe during an operation of a memory device, and FIG. 5B is a view showing that a probe is brought into contact with a hole of a two-dimensional material layer that is greater than a plane size of a predetermined height of the probe during an operation of a memory device. FIG. 6A is a micrograph illustrating a region including a heterogeneous domain formed when a probe is positioned as shown in FIG. 5A. FIG. 6B is a micrograph illustrating a region including a heterogeneous domain formed when a probe is positioned as shown in FIG. 5B. FIG. 7 is a micrograph of forming a heterogeneous domain in a memory device including MoTe₂ by using a method of operating the memory device, according to an example embodiment.

The second two-dimensional material region 122 and the third two-dimensional material region 123 may be locally formed in a region adjacent to the predetermined region T by applying a voltage to the predetermined region T of the two-dimensional material layer 100 including the first two-dimensional material region 121. Accordingly, a memory device 10 including a heterogeneous domain that is different from the first domain may be formed. Referring to FIG. 5A, the planar size of a depressed or removed region 110 of the first two-dimensional material region 121 may be less than the planar size of the height of the probe 200. The height of the probe 200 may be a predetermined height. If the probe 200 has a conical shape, the planar area of the probe 200 may increase as the height of the probe 200 increases. The predetermined height of the probe 200 may be less than the height when the plane of the probe 200 is the maximum, and the predetermined height plane of the probe 200 may be less than the maximum size of the plane of the probe 200. In this case, when the probe 200 penetrates the removed surface, the edge part (edge) of the probe 200 may entirely contact the circumference of the depressed or removed region 110 of the first two-dimensional material region 121 at a predetermined height before penetrating by the predetermined height. For example, at a predetermined height having a size equal to the penetration depth, the diameter of the probe 200 may be substantially the same as the diameter of the contact region 110, and the probe 200 may entirely contact the edge of the contact region 110.

According to another example embodiment, referring to FIG. 5B, the planar size of a depressed or removed region 110 of the first two-dimensional material region 121 may be greater than the planar size of the predetermined height of the probe 200. Here, the predetermined height of the probe 200 may be a value equal to the depth of the removed surface. In this case, when the probe 200 penetrates the removed surface by a predetermined height, the edge of the probe 200 may contact only a part of the circumference of the depressed or removed region 110 of the first two-dimensional material region 121. For example, if the diameter of the contact region 110 is greater than the diameter of the predetermined height of the probe 200, the probe 200 may only partially contact the two-dimensional material single layer 101 arranged uppermost.

FIG. 6A shows a memory device 10 formed by applying a voltage to a predetermined region T when the probe 200 is positioned as shown in FIG. 5A. When the edge of the probe 200 of the SPM entirely contacts the circumference of the depressed or removed region 110 of the first two-dimensional material region 121, a rhombus-shaped region including the heterogeneous domain may be formed around the predetermined region T. The second two-dimensional material region 122 may be formed in each of regions including two opposite sides of a rhombus, and the third two-dimensional material region 123 may be formed in each of regions including two opposite sides different from the two sides. In other words, the second two-dimensional material region 122 having the second domain may include the first sub-region and the second sub-region, and the first sub-region and the second sub-region may be arranged to face each other with respect to the contact region 110. The third two-dimensional material region 123 having the third domain may include the third sub-region and the fourth sub-region, and the third sub-region and the fourth sub-region may be arranged to face each other with respect to the contact region 110. Alternatively, the second two-dimensional material region 122 and the third two-dimensional material region 123 may be point-symmetric based on one point in the contact region 110. Referring to FIG. 7, the memory device 10 may include MoTe₂ having a heterogeneous 1T′ phase, and may include a region including a rhombus-shaped heterogeneous domain around the contact region 110.

FIG. 6B shows a memory device 10 formed by applying a voltage to a predetermined region T when the probe 200 is positioned as shown in FIG. 5B. When the edge of the probe 200 of the SPM contacts only a portion of the circumference of the depressed or removed region 110 of the first two-dimensional material region 121, a region including the triangle-shaped heterogeneous domain may be formed on the contact portion. The triangular region including the heterogeneous domain may correspond to half of the rhombic region including the heterogeneous domain. Each of the second two-dimensional material region 122 and the third two-dimensional material region 123 included in the region including the heterogeneous domain may also have a triangular shape.

As described above, the shape of the region and/or the shape of the boundary of the heterogeneous domain formed depending on the voltage applying position or the contact position of the probe 200 of the scanning probe microscope may vary.

The region including the locally formed heterogeneous domain may have a size of 200 nm² to 3000 nm², for example, a size of 500 nm² to 2200 nm². Alternatively, each of the second two-dimensional material region 122 and the third two-dimensional material region 123 may have a size of 100 nm² to 1500 nm², for example, a size of 250 nm² to 1100 nm².

The contact region 110 formed according to FIGS. 5A, 5B, 6A, 6B and 7 is a contact region in which a predetermined region T is depressed or etched to form a hole or groove, but the contact region 110 may be formed in the form of a step-terrace structure without being limited thereto. Alternatively, the contact region 110 may be formed without depressing or etching. For example, the contact region 110 may be a region contacting an edge of the two-dimensional material layer 100, and a thickness direction surface of the two-dimensional material layer 100 may be the contact region 110.

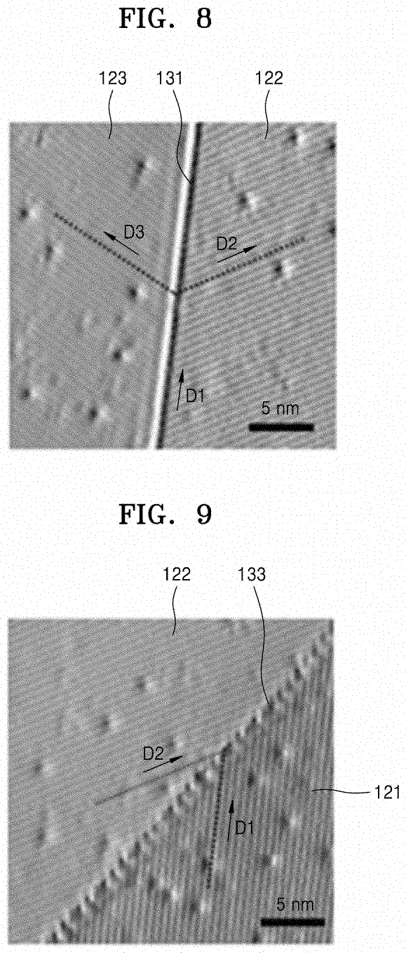

FIG. 8 is a micrograph of the second two-dimensional material region, the third two-dimensional material region, and the first boundary of FIG. 7. FIG. 9 is a micrograph of the first two-dimensional material region, the second two-dimensional material region, and the third boundary of FIG. 7.

Referring to FIGS. 6A, 6B, 7, 8 and 9, the memory device 10 according to an example embodiment may include at least one second two-dimensional material region 122 having the second domain and at least one third two-dimensional material region 123 having the third domain. The second domain may include a material having the heterogeneous 1T′ phase that is different from the 1T′ phase of the first domain of the first two-dimensional material region 121 surrounding the heterogeneous domain region. A predetermined atomic alignment direction of the first two-dimensional material region 121 and a predetermined atomic alignment direction of the second two-dimensional material region 122 may form a predetermined angle. For example, when the memory device 10 includes MoTe₂, the predetermined atoms may be tellurium positioned on the top (Top Te), and the two alignment directions may form an angle of 55 degrees to 65 degrees. For example, the Top Te alignment direction of the first two-dimensional material region 121 may form an angle of 60 degrees with the Top Te alignment direction of the second two-dimensional material region 122.

The third domain may include a material having the heterogeneous 1T′ phase that is different from the 1T′ phase of the first domain of the first two-dimensional material region 121 surrounding the heterogeneous domain region. A predetermined atomic alignment direction of the first two-dimensional material region 121 and a predetermined atomic alignment direction of the third two-dimensional material region 123 may form a predetermined angle. For example, when the memory device 10 includes MoTe₂, the predetermined atoms may be tellurium positioned on the top (Top Te), and the two alignment directions may form an angle of 55 degrees to 65 degrees. For example, the Top Te alignment direction of the first two-dimensional material region 121 may form an angle of 60 degrees with the Top Te alignment direction of the third two-dimensional material region 123.

The second domain may include a material having the heterogeneous 1T′ phase that is different from the 1T′ phase of the second two-dimensional material region 122. A predetermined atomic alignment direction of the second two-dimensional material region 122 and a predetermined atomic alignment direction of the third two-dimensional material region 123 may form a predetermined angle. For example, when the memory device 10 includes MoTe₂, the predetermined atoms may be tellurium positioned on the top (Top Te), and the two alignment directions may form an angle of 115 degrees to 125 degrees. For example, the Top Te alignment direction of the second two-dimensional material region 122 may form an angle of 120 degrees with the Top Te alignment direction of the third two-dimensional material region 123.

A first boundary 131 may be formed between the second two-dimensional material region 122 having the second domain and the third two-dimensional material region 123 having the third domain. A second boundary 132 may be formed between the first two-dimensional material region 121 having the first domain and the third two-dimensional material region 123 having the third domain. A third boundary 133 may be formed between the first two-dimensional material region 121 having the first domain and the second two-dimensional material region 122 having the second domain. The first boundary 131 may have the same direction as the alignment direction of predetermined atoms included in the first two-dimensional material region 121. Each of the first boundary 131, the second boundary 132, and the third boundary 133 may be a grain boundary. Each of the first boundary 131, the second boundary 132, and the third boundary 133 may have different properties from the first domain, the second domain, and the third domain.

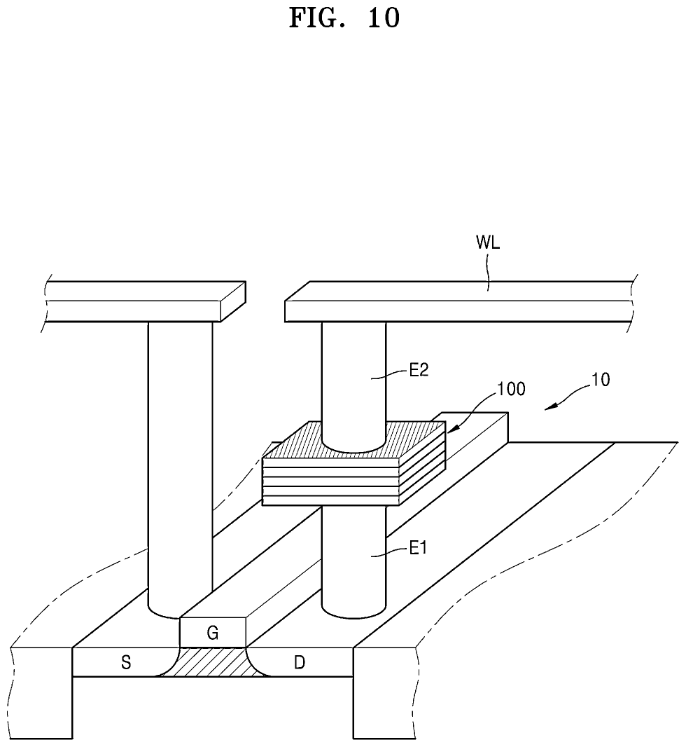

FIG. 10 is a conceptual diagram illustrating a memory device according to an example embodiment.

Referring to FIG. 10, the memory device 10 according to an example embodiment may be a memory device using a change in resistance according to a phase. The memory element 10 may further include a source region S, a drain region D, and a gate structure G A two-dimensional material layer 100 may be arranged on the source region S or the drain region D The two-dimensional material layer 100 may be electrically connected to the source region S or the drain region D through a first electrode E1 or a second electrode E2. The source region S and the drain region D may be spaced apart from each other. The memory device 10 may include the first electrode E1 and the second electrode E2, and a two-dimensional material layer 100 may be arranged between the first electrode E1 and the second electrode E2. The first electrode E1 may be one of a source electrode and a drain electrode, and the second electrode E2 may be an electrode connected to a word line WL.

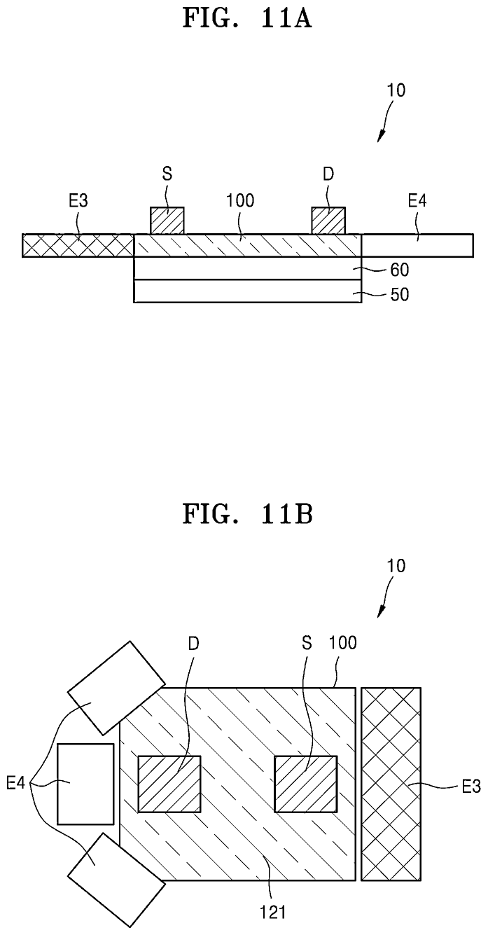

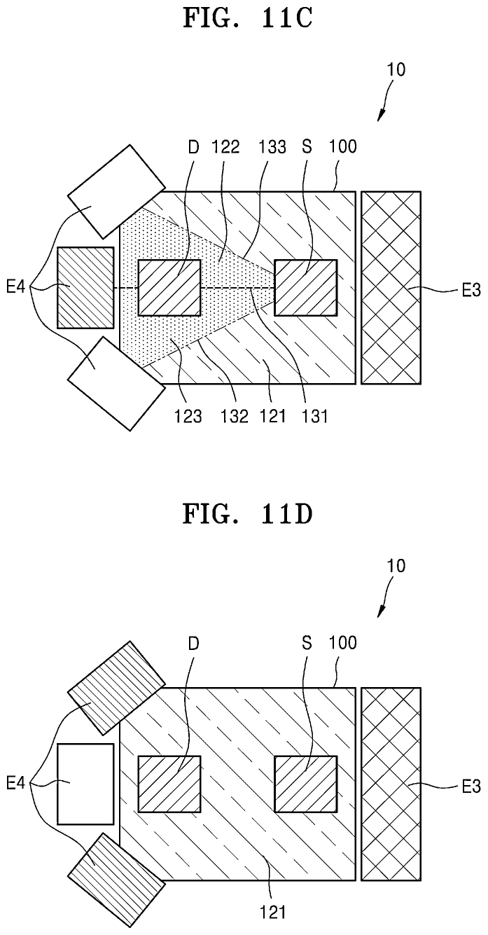

FIGS. 11A and 11B are a cross-sectional view and a plan view of a memory device according to an example embodiment, respectively. FIG. 11C and FIG. 11D are conceptual views illustrating that an electrode connected to the memory device of FIG. 11B is used to cause phase change of the memory device.

Referring to FIGS. 11A to 11B, the memory device 10 according to an example embodiment may be arranged on a substrate 50 and an insulating layer 60, and the source region S and the drain region D may be spaced apart from each other on the upper surface of the two-dimensional material layer 100 of the memory device 10. The memory device 10 may include a third electrode E3 and a fourth electrode E4, in which the third electrode E3 may be arranged close to the source region S, and the fourth electrode E4 may be arranged close to the drain region D. In FIG. 11B, the surface of the initial two-dimensional material layer 100 in contact with the source region S and the drain region D may include the first two-dimensional material part 121.

The third electrode E3 and the fourth electrode E4 may contact each edge of the two-dimensional material layer 100 to apply a voltage to the memory element 10. However, the embodiments are not limited thereto, and a hole, groove, or step-terrace structure which each of the third electrode E3 and the fourth electrode E4 can contact may be formed in the memory device 10.

The substrate 50 included in the example memory device 10 may include a semiconductor material, for example, silicon (Si). The insulating layer 60 included in the example memory device 10 may include a dielectric material, for example, silicon dioxide (SiO₂).

Referring to FIG. 11C, the fourth electrode E4 may include a first electrode element, a second electrode element, and a third electrode element. When the second electrode elements of the third electrode E3 and the fourth electrode E4 are switched on and the first electrode elements and the third electrode elements thereof are switched off, a surface of the two-dimensional material layer 100 in contact with the drain region D may be phase-changed. For example, a surface of the two-dimensional material layer 100 in contact with the drain region D may include at least one of the second two-dimensional material region 122 and the third two-dimensional material region 123. When the surface includes both the second two-dimensional material region 122 and the third two-dimensional material region 123, the first boundary 131 may also be included therein. In the switch-on state, a surface of the two-dimensional material layer 100 in contact with the source region S may not be phase-changed. For example, a surface of the two-dimensional material layer 100 in contact with the source region S may include the first two-dimensional material region 121. However, the embodiments are not limited thereto, and a portion of the surface of the memory element 10 in contact with the source region S may include at least one of the second two-dimensional material region 122 and the third two-dimensional material region 123, and at least one of the second two-dimensional material region 122 and the third two-dimensional material region 123 may be formed over the entire surface.

Referring to FIG. 11D, when the first electrode elements and the third electrode elements of the third electrode E3 and the fourth electrode E4 are switched on and the second electrode elements thereof are switched off, a surface of the two-dimensional material layer 100 in contact with the drain region D may be phase-changed again and may be recovered. In this case, the surface of the two-dimensional material layer 100 in contact with the source region S and the drain region D may be the first two-dimensional material region 121.

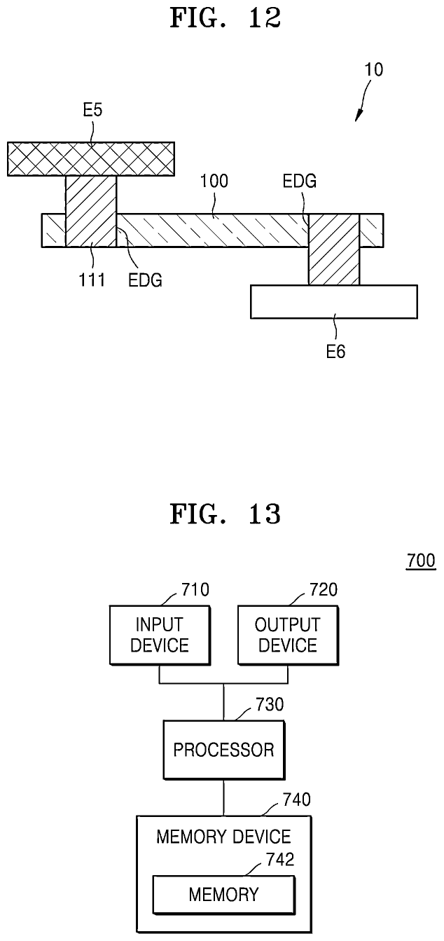

FIG. 12 is a cross-sectional view illustrating a memory device according to an example embodiment.

Referring to FIG. 12, a fifth electrode E5 and a sixth electrode E6 of the memory device 10 according to an example embodiment may be electrically connected to the two-dimensional material layer 100 through a contact part 111. A voltage may be applied to the edge part EDG of the two-dimensional material layer 100 through the fifth electrode E5 and the sixth electrode E6, and thus the two-dimensional material layer 100 may be phase-changed. Here, the edge part EDG may correspond to the contact region 110.

The memory device 10 according to an example embodiment includes the first two-dimensional material region 121, the second two-dimensional material region 122, and the third two-dimensional material region 123 each having the different domain. Each of the first domain, the second domain, and the third domain may have a heterogeneous 1T′ phase, and each heterogeneous 1T′ phase may have a different alignment direction of predetermined atoms included in the material. Accordingly, at least two of the first two-dimensional material region 121, the second two-dimensional material region 112, and the third two-dimensional material region 123 may have different properties in physical properties or chemical properties, for example, electrical properties, optical properties, thermal properties, magnetic properties, crystalline structural properties, or the like. For example, the properties may include thermal conductivity, electrical conductivity, lattice constant, refractive index, magnetic resistance, and the like. In addition, the boundaries formed between different two-dimensional material regions may have properties different from those of each two-dimensional material region. Due to the above features, the memory device 10 according to an example embodiment or the method of forming the memory device 10, according to an example embodiment, may be applied to a two-dimensional semiconductor TMD device, ferroelastic domain switching, ohmic contact, and the like, and may be also used for a memristor device, a spintronics, ferroelectric and shape memory device, a phase change memory device, an electronic device, and the like. For example, the method of forming the memory device 10, according to an example embodiment, may be applied to the use of a two-dimensional phase change random access memory device.

FIG. 13 is a block diagram of an electronic device including a memory device according to an example embodiment.

Referring to FIG. 13, the electronic device 700 includes an input device 710, an output device 720, a processor 730, and a memory device 740. In some embodiments, the memory device 740 may include a cell array including a nonvolatile memory cell and a peripheral circuit for an operation such as read/write. In some other embodiments, the memory device 740 may include a nonvolatile memory device and a memory controller.

A memory 742 included in the memory device 740 may include the memory device 10 according to the embodiments described with reference to FIGS. 1 to 12.

The processor 730 may be connected to the input device 710, the output device 720, and the memory device 740 through an interface to control the overall operation.

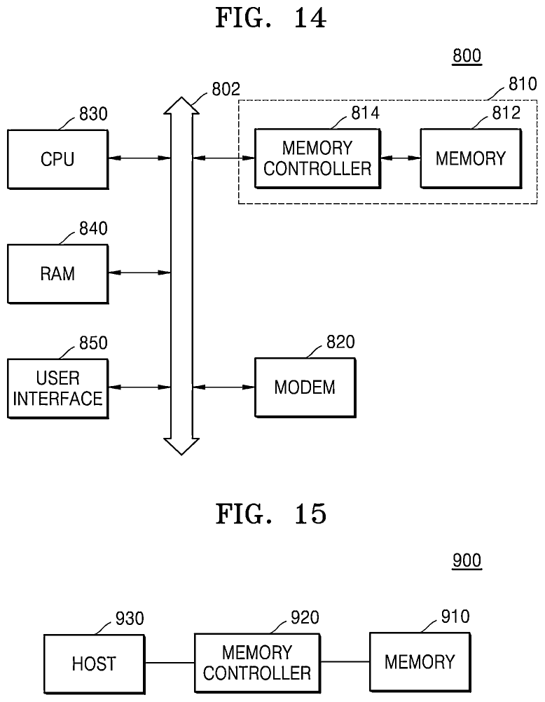

FIG. 14 is a block diagram of an information processing system including a memory device according to an example embodiment.

Referring to FIG. 14, the information processing system 800 includes a nonvolatile memory system 810, a modem 820, a central processing unit 830, a RAM 840, and a user interface 850, which are electrically connected to a bus 802.

The nonvolatile memory system 810 may include a memory 812 and a memory controller 814. The nonvolatile memory system 810 stores data processed by the central processing unit 830 or data input from the outside.

The nonvolatile memory system 810 may include a nonvolatile memory such as a MRAM, a PRAM, a RRAM, a FRAM, or the like. At least one of the memory 812 and the RAM 840 may include the memory device 10 according to the embodiments described with reference to FIGS. 1 to 12.

The information processing system 800 may be applied to portable computers, web tablets, wireless phones, mobile phones, digital music players, memory cards, MP3 players, navigation devices, portable multimedia players (PMPs), solid state disks (SSDs), household appliances, wearable devices such as smart watches, head mounted displays, head-up displays, augmented reality and/or virtual reality glasses, autonomous vehicles, and the like.

FIG. 15 is a block diagram of a memory card including a memory device according to an example embodiment.

The memory card 900 includes a memory 910 and a memory controller 920.

The memory 910 may store data. In some embodiments, the memory 910 has a nonvolatile characteristic capable of maintaining stored data even when power supply is interrupted. The memory 910 may include the memory device 10 according to the embodiments described with reference to FIGS. 1 to 12.

The memory controller 920 may read data stored in the memory 910 or store data in the memory 910 in response to a read/write request of the host 930.

A domain of the memory device according to the above example embodiment may be changed as a voltage is applied to a local region, and thus may be implemented as a memory device. In addition, at least two of the first two-dimensional material region, the second two-dimensional material region, and the third two-dimensional material region included in the memory device according to an example embodiment may be different from each other in at least one of electrical properties, optical properties, thermal properties, magnetic properties, or crystalline structural properties, to thus be implemented as a memory device.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A memory device comprising:
a two-dimensional material layer including a two-dimensional material;
a contact region at an edge of the two-dimensional material layer; and
one or more electrodes which are electrically connected to the contact region and configured to apply voltage to change a domain of an adjacent region, which is adjacent to the contact region of the two-dimensional material layer.

2. The memory device of claim 1, wherein
the two-dimensional material layer comprises a first two-dimensional material region having a first domain,
based on a first voltage being applied by a first electrode among the one or more electrodes, the adjacent region is changed into a second two-dimensional material region having a second domain that is different from the first domain and a third two-dimensional material region having a third domain, and
based on a voltage being applied by a second electrode among the one or more electrodes, the adjacent region is changed into the first two-dimensional material region.

3. The memory device of claim 2, wherein first atoms included in the first two-dimensional material region are aligned in a first direction, second atoms included in the second two-dimensional material region are aligned in a second direction, and third atoms included in the third two-dimensional material region are aligned in a third direction.

4. The memory device of claim 3, wherein an angle between the first direction and the second direction is 55 degrees to 65 degrees, an angle between the first direction and the third direction is 55 degrees to 65 degrees, and an angle between the second direction and the third direction is 115 degrees to 125 degrees.

5. The memory device of claim 3, wherein
the first atoms are located at an uppermost end of a plurality of atoms included in the first two-dimensional material region, the second atoms are located at an uppermost end of a plurality of atoms included in the second two-dimensional material region and the third atoms are located at an uppermost end of a plurality of atoms included in the third two-dimensional material region, and
the first domain, the second domain, and the third domain have 1T′ phases having different alignment directions of the atoms, respectively.

6. The memory device of claim 2, wherein at least two of the first two-dimensional material region, the second two-dimensional material region, and the third two-dimensional material region have different properties in at least one of electrical properties, optical properties, thermal properties, magnetic properties, or crystalline structural properties.

7. The memory device of claim 2, wherein a first boundary between the second two-dimensional material region and the third two-dimensional material region has a same direction as an alignment direction of atoms included in the first two-dimensional material region.

8. The memory device of claim 2, wherein
the second two-dimensional material region comprises a first sub-region and a second sub-region facing each other based on the contact region,
the third two-dimensional material region comprises a third sub-region and a fourth sub-region facing each other based on the contact region, and
the first sub-region, the second sub-region, the third sub-region, and the fourth sub-region form a rhombic shape.

9. The memory device of claim 2, wherein at least one of the second two-dimensional material region or the third two-dimensional material region has a triangular shape.

10. The memory device of claim 2, wherein a region including the second two-dimensional material region and the third two-dimensional material region has a size of 200 nm² to 3000 nm².

11. The memory device of claim 1, wherein the contact region comprises at least one of a hole structure, a groove structure, or a step terrace structure.

12. The memory device of claim 1, wherein the contact region has a long-axis length of 10 nm to 200 nm.

13. The memory device of claim 1, wherein the contact region has a depth of 0.07 nm to 1 nm.

14. The memory device of claim 1, wherein the two-dimensional material comprises transition metal dichalcogenide (TMD).

15. The memory device of claim 1, wherein the two-dimensional material comprises at least one of MoS₂, MoTe₂, MoSe₂, WS₂, WSe₂, or WTe₂.

16. The memory device of claim 1, wherein the voltage is applied by the one or more electrodes at a direction parallel to a planar surface of the two-dimensional material layer.

17. The memory device of claim 1, wherein the voltage applied by the one or more electrodes is −2 V to −4 V.

18. The memory device of claim 1, wherein the voltage applied by the one or more electrodes is applied for 50 ms to 400 ms.

19. The memory device of claim 1, further comprising:
a source region; and
a drain region spaced apart from the source region.

20. An electronic device comprising:
a memory device comprising:
a two-dimensional material layer including a two-dimensional material;
a contact region at an edge of the two-dimensional material layer; and
one or more electrodes which are electrically connected to the contact region and configured to apply voltage to change a domain of an adjacent region, which adjacent to the contact region of the two-dimensional material layer.
